(19) United States
(12) Patent Application Publication
(10) Pub. No.: US 2015/0206989 A1
(43) Pub. Date: Jul. 23, 2015

(54) SEMICONDUCTOR COMPONENT WITH A PASSIVATION LAYER MADE OF HYDRATED ALUMINIUM NITRIDE AND ALSO METHOD FOR SURFACE PASSIVATION OF SEMICONDUCTOR COMPONENTS

(71) Applicant: FRAUNHOFER-GESELLSCHAFT ZUR FÖRDERUNG DER ANGEWANDTEN FORSCHUNG E.V., München (DE)

(72) Inventors: Winfried Wolke, Freiburg (DE); Florian Wagner, Freiburg (DE); Georg Krugel, Freiburg (DE)

(73) Assignee: FRAUNHOFER-GESELLSCHAFT ZUR FORDERUNG DER ANGEWANDTEN FORSCHUNG E.V., Munchen (DE)

(21) Appl. No.: 14/421,624

(22) PCT Filed: Aug. 16, 2013
(86) PCT No.: PCT/EP2013/067108

§ 371 Date: Feb. 13, 2015

(30) Foreign Application Priority Data
Aug. 16, 2012 (DE) 10 2012 016 298.7

(51) Int. Cl. H01L 31/0216; H01L 31/18

(52) U.S. Cl. CPC H01L 31/02167; H01L 31/1868

(57) ABSTRACT

The invention relates to a semiconductor component with base emitter and electrical contacts and also at least one passivation layer which consists of hydrated aluminium nitride or essentially comprises this. The invention relates likewise to a corresponding method for surface passivation of semiconductor components.

The invention relates to a semiconductor component with base emitter and electrical contacts and also at least one passivation layer which consists of hydrated aluminium nitride or essentially comprises this. The invention relates likewise to a corresponding method for surface passivation of semiconductor components.

Industrial manufacture of solar cells is already subject to efforts, purely for reasons of competition, to produce solar cells with as high efficiency as possible, i.e. as high an electrical current output as possible, from the solar energy flow impinging on the solar cell and, at the same time, to keep low the manufacturing complexity and, closely associated therewith, the production costs.

The subsequent explanations are intended to serve for greater understanding of the measures to be considered in optimised manufacture of solar cells.

Solar cells are components which convert light into electrical energy. Normally, they consist of a semiconductor material generally solar cells are manufactured from silicon which has n- or p-doped semiconductor regions. The semiconductor regions are termed, as known per se, emitter or base. As a result of light impinging on the solar cell, positive and negative charge carriers are produced inside the solar cell which, at the interface between the n- (emitter) and p-doped (base) semiconductor region, are separated from each other spatially at the so-called p-n junction. By means of metallic contacts which are connected to the emitter and to the base, these charge carriers which are separated from each other can be led away.

In the simplest form, solar cells consist of all-over base and emitter regions, the emitter being situated on the side orientated towards the light, the front-side of the solar cell.

For electrical contacting of the base, the rear-side of the solar cell is usually provided with an all-over metal layer on which suitable rear-side contact strip conductors, e.g. made of AgAl, are applied. The emitter region is contacted with a metal grid with the aim of losing as little light as possible by reflection on the metal contact for the solar cell, i.e. the metal grid has a finger structure in order to cover as little as possible of the solar cell surface. For optimisation of the output yield of the solar cell, it is attempted in addition to keep the optical losses based on reflection as low as possible. This is achieved, on the one hand, by deposition of so-called antireflection coatings (ARC) on the front-side surface of the solar cell. The layer thickness of the antireflection coatings is chosen such that, in the energetically most important spectral range, precisely destructive interference of the reflected light is produced. Antireflection materials which are used are, for example, titanium dioxide, silicon nitride and silicon dioxide. For application of these layers, there are various approaches, such as e.g. thermal growing, coating by chemical vapour deposition (CVD) or by physical vapour deposition (PVD). A further possibility for reducing reflections resides in the structuring of the front-side surface of the silicon wafer.

A further feature of highly efficient solar cells is narrow (<40 μm) and high front-side contacts (<10 μm) with low contact- and conduction resistance.

The surfaces of solar cells of high efficiency are distinguished, besides good electrical contactings, in addition by a low surface recombination rate, i.e. the probability is low that minority charge carriers reach the surface of the solar cell and recombine there and hence do not contribute to energy production, as a result of which the outcome is a significant reduction in efficiency.

This can be achieved either by few minority charge carriers reaching the surface or by them recombining only with a low probability on the surface.

Preventing migration of the minority charge carriers to the surface can be achieved by high doping of foreign atoms being produced in the region of the surface or by a dielectric layer being applied on the surface and fixed charges being incorporated in the interface between semiconductor and dielectric layer. High doping is produced by emitter doping with different degrees of intensity on the front-side. High doping is however always associated with the disadvantage that although the recombination probability on the surfaces of the solar cell can be reduced, instead the recombination probability inside the solar cell layer is however increased. Charges can be incorporated, for example also by means of a layer of silicon nitride which serves particularly well as antireflection coating. The number of charges is characterised by the value Q_{f}.

Reducing the recombination on the surface can be achieved by reducing the surface recombination states, e.g. by open and hence unsaturated silicon bonds on the surface being saturated by a layer of amorphous silicon, silicon nitride, aluminium oxide or silicon dioxide which, as described above, can be used on the front-side in part also as antireflection coating. The number of open bonds is characterised by the imperfection density Dᵢₜ. The passivation can be applied both on the front- and on the rear-side and is one of the most important features of highly efficient solar cells.

The advantages and disadvantages of the various methods for surface passivation which correspond to the current state of the art are intended to be explained subsequently:

1. Growth of silicon dioxide on the Si surface

The very good passivation effect (A. G. Aberle, Crystalline silicon solar cells—Advanced surface passivation and analysis, University of New South Wales (1999)) of thermal silicon oxides on p- and n-type surfaces is faced with several disadvantages. On the one hand, due to a refractive index of n=1.48 at 600 nm, the layer cannot be applied on the front-side as single-layer antireflection coating. On the other hand, the process of thermal layer growth with rates in the range of 1-5 nm/min, compared with PECVD and PVD deposition of Si(O)N with rates around 1 nm/s, is significantly slower and consequently more cost-intensive. As a result of the high thermal budget, in addition undesired changes in emitter profile can take place. Not least, it must always be ensured during oxidation that a directed process is in principle not involved. A layer growth on surfaces which are not to be coated can therefore only be prevented by a diffusion barrier.

2. Coating of the surface with hydrated silicon nitride (SiN:H) and/or with silicon oxynitride (SiNO:H)

Layers made of SiN:H or SiNO:H which are deposited by means of CVD or PVD methods have high deposition rates and consequently low production costs. For these layers, the disadvantage resides rather in the scope of achievable passivation quality as a function of high-temperature processes which follow the coating (S. W. Glunz, A. Grohe, M. Hermle, M. Hofmann, S. Janz, T. Roth, O. Schultz, M. Vetter, I. Martin, R. Ferre, S. Bermejo, W. Wolke, W. Warta, R. Preu and G. Willeke, Comparison of different dielectric passivation layers for application in industrially feasible high-efficiency crystalline silicon solar cells, in Proceedings of the 20^{th} European Photovoltaic Solar Energy Conference, 2005, Barcelona, Spain: p. 572-7). In the case of optimised stack systems made of silicon oxynitride plus silicon nitride, results which are based on the use of n-type surfaces are revealed. (C. Schwab, M. Hofmann, J. Rentsch, R. Preu, Front surface passivation for industrial-type solar cells by silicon nitride stacks, in proceedings of the 25^{th} European Photovoltaic Solar Energy Conference, 2010, Valencia, Spain). The use of SiN:H for passivation of p-type surfaces, such as e.g. the rear-side of highly efficient silicon solar cells (with p-type base), is associated with difficulties. The reason resides in the formation of fixed positive charges in the SiN:H layer which leads, during deposition on p-type surfaces, to a reversal of the charge carrier ratios (inversion) on the silicon surface. The result of this is a reduction in efficiency of the solar cell if this surface, as is normal with high-efficiency solar cells, is contacted locally without a barrier being produced relative to the contact for the majority of the inversion layer (minority in the base). The result then is a leakage current (inversion layer shunting).

3. Coating of the surface with aluminium oxide (AlO)

In contrast to SiN:H, AlO has a large number of negative charges in the layer. In addition to the high negative charge density Q_{f}, low defect densities Dᵢₜ (around 1*10¹¹ eV⁻¹cm⁻²) are achieved during deposition of AlO by means of PVD, CVD or ALD. This leads to a very good passivation effect of AlO (On the c-Si surface passivation mechanism by the negative charge dielectric Al203; B. Hoex, J. Giehlus, M. Sanden, W. Kessels, Journal of Applied Physics, 2008). As a result of the negative charges, the use on p-type surfaces is advantageous since an accumulation zone is formed which in fact easily enhances the majority flow into the contacts. Technical disadvantages of the aluminium oxide produced in the CVD or ALD method are for example the necessary use of expensive organic precursors (normally TMAl, tetramethylaluminium) for preparing the aluminium. Furthermore, aluminium oxide has an optically unfavourable refractive index of 1.7 for some applications.

Starting herefrom it was the object of the present invention to provide an improved passivation of the surface of solar cells which can be integrated easily into the production process.

This object is achieved by the solar cell having the features of claim 1 and the method for surface passivation of solar cells having the feature of claim 9. The further dependent claims reveal advantageous developments.

According to the invention, a solar cell with base, emitter and metallic contacts connected respectively electrically to the base and to the emitter and also at least one passivation layer for the front-side surface orientated towards the light source and/or the rear-side surface orientated away from the light source is provided. It is sensible and essential here that the at least one passivation layer consists of hydrated aluminium nitride or essentially comprises this.

Surprisingly, it was found that a passivation layer obtained in this way has an extremely low surface recombination rate, measured by means of quasi-steady-state photoconductance (quasi-steady-state photoconductance QSSPC) and hence an extremely long lifespan of the separated charge carriers. This low surface recombination rate can be reduced once again if a thermal treatment of the passivation layer(s) is implemented. Preferably, the at least one passivation layer has a refractive index, measured by means of ellipsometry at 600 nm, in the range of 1.9 to 2.2. The mentioned measuring methods are described in more detail further on.

This means that hydrated AlN can be used very well as antireflection coating. Which is to say an advantage results relative to the initially described method 1 and 3.

On the side of the passivation layer orientated away from the emitter, preferably at least one further layer, in particular a layer which comprises hydrated silicon nitride or consists thereof, and/or a silicon oxide layer and/or a silicon oxynitride layer, can be deposited. The passivation layer hence represents a first layer in a stack system made of a plurality of layers. Likewise, an iterative arrangement of a plurality of passivation layers and a plurality of further layers in a stack system is conceivable, e.g. an alternating arrangement of 2-10 passivation layers and a corresponding number of further layers. On the basis of the fact that the mentioned further layers, in particular the layers comprising silicon, have a greater refractive index than the passivation layer(s), consequently antireflection of such a layer composite and hence dereflecting of the solar cell can be achieved at the same time.

Preferably, between the semiconductor component and the passivation layer, the semiconductor component has a native oxide layer or an oxide layer with a thickness of less than or equal to 3 nm.

At least one, preferably every passivation layer and/or at least one, preferably every further layer, has preferably a layer thickness in the range of 1 to 200 nm, in particular in the range of 30 to 80 nm.

According to the invention, a method for surface passivation of solar cells is likewise provided, in which, on the front-side surface orientated towards the light source and/or on the rear-side surface of the semiconductor component orientated away from the light source, at least one passivation layer made of hydrated aluminium nitride is deposited by means of vapour deposition from an atmosphere comprising aluminium, nitrogen and hydrogen. The main components of the solar cells thereby correspond to those mentioned initially.

Preferably, the vapour deposition is effected by means of physical vapour deposition (PVD), chemical vapour deposition (CVD), plasma-enhanced chemical vapour deposition (PE-CVD), chemical vapour deposition under atmospheric pressure (AP-CVD) or atomic layer deposition (ALD). This has the advantage that PVD and CVD have significantly higher deposition rates compared with thermal growth. The method according to the invention hence has, relative to method 1 described initially, a significant production cost- and throughput advantage.

In the case of vapour deposition, preferably nitrogen and hydrogen are thereby used in atomic and/or molecular form, in particular N₂, H₂, and/or NH₃. Relative to method 3 described initially, this has the advantage that oxygen is used as process gas. With comparable purity, oxygen is, on the one hand, more expensive than nitrogen by an order of magnitude, on the other hand, it is substantially more critical, with respect to safety aspects, such as e.g. danger of explosion with simultaneous use of oxygen and hydrogen (in the deposition of hydrogen-containing AlO:H layers). The method according to the invention hence has significant cost advantages and simpler technical process handling relative to method 3. As described above, the use as antireflection coating is possible in addition in the case of the method according to the invention, in contrast to method 3.

As non-reactive gas which is used in particular in physical vapour deposition methods, a noble gas is used preferably, in particular argon.

Preferably, introduction of the hydrogen into the passivation layer is effected with at least one of the following techniques:
incorporation or implantation during vapour deposition,
introduction by means of diffusion from the gas phase or from a layer comprising hydrogen which is deposited on the passivation layer.

Furthermore, it is preferred that, during the vapour deposition, aluminium is used or generated in atomic or molecular form, in particular trimethylaluminium (TMA).

A further preferred variant provides that, after the vapour deposition, the passivation layer is subjected to a temperature treatment at temperatures of 350 to 900° C.

Such a temperature treatment can be designed for example as rapid thermal processing (RTP); a short thermal treatment at high temperatures is hereby implemented, e.g. a treatment at temperatures between 700° C. and 900° C., preferably between 800° C. and 900° C., over a period of time of 0.1 to 10 s, preferably 0.1 to 5 s.

Likewise, also a temperature treatment over a longer period of time and at lower temperatures is however possible and suitable, this is hereby termed so-called “annealing”. Such a treatment is implemented preferably in the temperature range of 350° C. and 600° C., preferably 350° C. and 450° C., over a period of time of 0.5 min to 1 h, preferably 1 min to 15 min.

The temperature treatment leads to a significantly reduced imperfection density in the passivation layer which is preferably 1×10¹³ eV⁻¹cm⁻², further preferred <10×10¹⁰ eV⁻¹ cm⁻², preferably <5×10¹⁰ ev⁻¹cm⁻².

The subject according to the invention is intended to be explained in more detail with reference to the subsequent Figures without wishing to restrict said subject to the specific embodiments shown here.

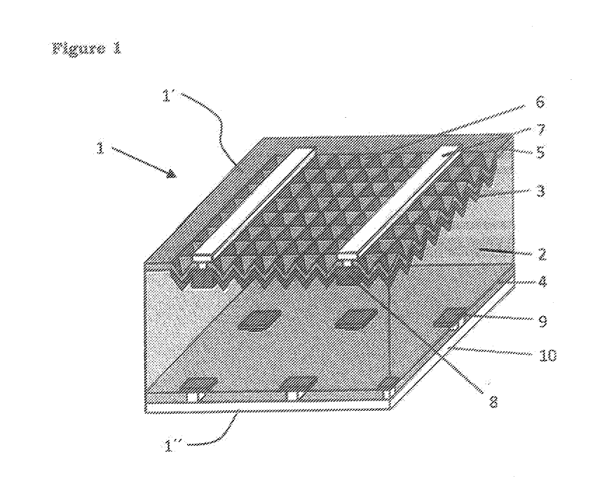

FIG. 1 shows the schematic construction of a highly efficient solar cell according to the state of the art.

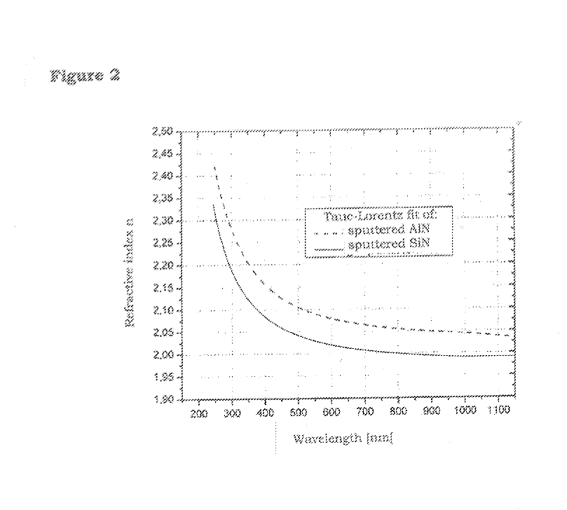

FIG. 2 shows a diagram of the dependence of the extinction coefficient upon the wavelength for sputtered layers of hydrated aluminium nitride and hydrated silicon nitride.

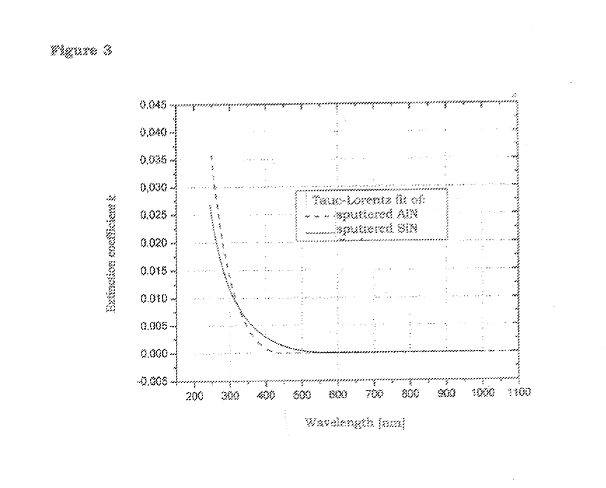

FIG. 3 shows a diagram of the dependence of the refractive index upon the wavelength for layers of sputtered hydrated aluminium nitride and hydrated silicon nitride.

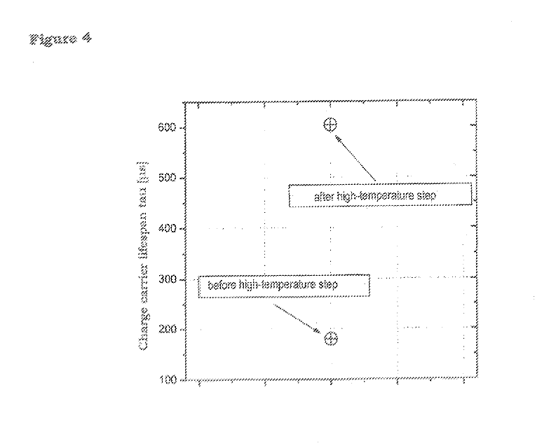

FIG. 4 shows by means of a diagram, by way of comparison, the charge carrier lifespan of solar cells passivated with hydrated aluminium nitride before and after a high-temperature step.

In FIG. 1, a solar cell which was described as state of the art in the introduction to the description is illustrated. A highly efficient solar cell 1 is illustrated herein, which, in addition to the base 2 and the emitter 3, has passivation layers 4 and 5 respectively on the front-side 1′ and rear-side 1″ of the solar cell. The front-side thereby has texturing 6 in the form of inverted or also random pyramids. Furthermore, a metallisation grid 7 which is connected to the selective emitter 8 is applied on the front-side. On the rear-side, a so-called local back surface field 9 is disposed next to the passivation layer 4. Finally a metallisation 10 is situated on the rear-side.

In contrast to method 1, the AlN:H layer is not intended to be grown thermally but rather deposited by means of CVD methods or PVD methods (e.g. by argon sputtering of an aluminium target with the addition of nitrogen/ammonia and hydrogen). In the case of the high-temperature processing of silicon surfaces passivated with AlN:H, a significant improvement in the surface passivation results. Saturation of the imperfections which can be achieved with method 2 after a high-temperature step is in a range of 1-5*10¹² eV⁻¹cm⁻². In the case of the silicon wafers according to the invention with AlN:H, a very low imperfection density of below 5*10¹⁰ ev⁻¹cm⁻² could be observed after a high-temperature step. This explains the good quality of the passivation. In summary, it can be established that, with respect to the thermal stability, the method according to the invention is significantly advantageous relative to method 2.

For the method according to the invention, nitrogen and hydrogen and/or ammonia is required as source gas.

In the diagram according to FIG. 2, the wavelength-dependent refractive indices of sputtered AlN:H and sputtered SiN:H are illustrated.

FIG. 3 shows the wavelength-dependent extinction coefficients of sputtered AlN:H and sputtered SiN:H.

With respect to the measuring methods for determining the refractive indices and also extinction coefficients, reference is made to the explanations further on.

In FIG. 4, the diagram illustrated there shows the results of a quasi-steady-state photoconductivity measurement (QSSPC) of a semiconductor component according to the invention which has a passivation made of hydrated aluminium nitride. A comparison of the charge carrier lifespan before and after the temperature-treatment step at 800° C. over 1 s was hereby effected. It was clearly shown hereby that the charge carrier lifespans could be increased by the high-temperature treatment step of 200 microseconds to 600 microseconds. In addition, a pressure treatment can be implemented before or after the temperature treatment. The measuring methodology (QSSPC) is subsequently described in more detail.

Spectrally Resolved Ellipsometry

Spectrally resolved ellipsometry is a method for examining the optical properties of thin layers. It allows determination of the layer thickness and of the complex refractive index.

\tilde{N}(λ)=n(λ)+ik(λ)

with
n real part of the refractive index
k extinction coefficient: imaginary part of the refractive index.

k is a measure of the absorption a in the material

$$α ( λ ) = \frac{4 π k ( λ )}{λ}$$

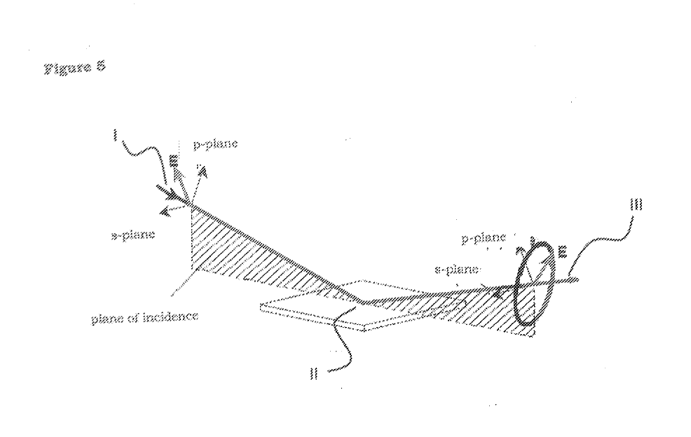

The measuring principle is illustrated in FIG. 5. In ellipsometry, light with a known polarisation, i.e. known quantity of vectorial components “s-plane” and “p-plane”, is guided at a defined angle (“plane of incidence”) (I) to a sample. When passing through the layer to be examined, the polarisation of the light is changed (II), i.e. a change in the size of the vectorial components “s-plane” and “p-plane” takes place. The state of the polymerisation is measured thereafter (III).

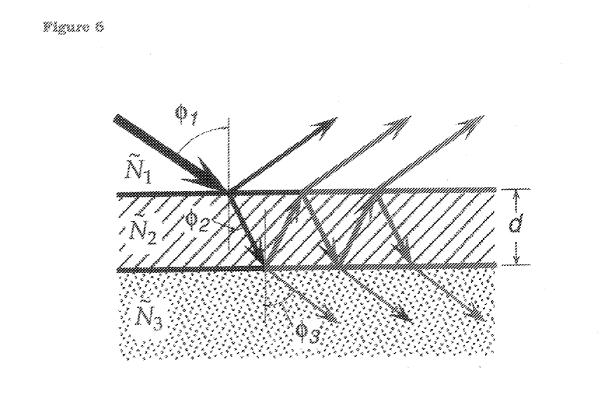

If light impinges on a sample with a thin layer (see FIG. 6 which illustrates the principle of light reflection on a thin layer of thickness d on a substrate (the thin layer hereby has the refractive index N₂, the substrate the refractive index N₃ and the surrounding medium the (refractive index N₁), typically multiple reflections take place on the surface of the layer. Interference of the incident light thereby takes place due to reflection on the respective interfaces of the thin layer, for example on the interface to air or vacuum (refractive index N₁) or to the medium on which the thin layer was grown (refractive index N₃). Any further transmission back into the medium 1 will be smaller with respect to the intensity than the previous one. The infinite series of partial waves together forms the resulting reflected wave.

Polarised light can be described by two vectors \vec{E}ₛ and \vec{E}ₛ which are perpendicular to each other. \vec{E}ₚ is parallel to the plane of incidence (p=parallel), \vec{E}ₛ is perpendicular to the plane of incidence (s=perpendicular).

Fresnel showed that reflected polarised light can be described as follows.

$$\frac{{R}_{p}}{{R}_{s}} = tan ( ψ ) \cdot {e}^{iΔ}$$

with
Ψ amplitude ratio,
Δ phase difference,
Rₚ reflection coefficient of the p-polarised light,
Rₛ reflection coefficient of the s-polarised light.

The reflection coefficient can be obtained from the following formulae

$${R}_{p} = \vert \frac{\vec{{E}_{p , r}}}{\vec{{E}_{p , l}}} \vert \cdot exp ( i ( {δ}_{r} - {δ}_{i} ) )$$

$${R}_{p} = \vert \frac{\vec{{E}_{s , r}}}{\vec{{E}_{s , l}}} \vert \cdot exp ( i ( {δ}_{r} - {δ}_{i} ) )$$

with
δᵢ phase angle of the incident light,
δᵣ phase angle of the reflected light.

An ellipsometric measurement provides experimental sets of data of Ψₑₓₚ and Δₑₓₚ. In order to determine the desired values, such as e.g. layer thickness and refractive index, a fit procedure is implemented using a model of the actual physical system. For the model, sets of Ψₑₓₚ and Δₑₓₚ are calculated and compared with the measuring data. Thereafter, a small change in the model is undertaken and compared again with the measuring data. This procedure is implemented several times until a minimum is achieved in the difference between the applied model and the actual data. The difference between the actual- and model data is treated mathematically by applying the mean squared error (MSE):

$$MSE = \sqrt{\frac{1}{2 N - M} {\sum }_{i = 1}^{N} ⌊ {( \frac{{ψ}_{mod , i} - {ψ}_{exp , i}}{{σ}_{exp , ψ , i}} )}^{2} + {( \frac{{Δ}_{mod , i} - {Δ}_{exp , i}}{{σ}_{exp , Δ , i}} )}^{2} ⌋}$$

As example: The simple Cauchy Model for the real part of the refractive index is a limited series development

$$n ( λ ) = A + \frac{B}{{λ}^{2}} + \frac{C}{{λ}^{4}}$$

This model can often be applied successfully for non-absorbing layers,

Quasi-steady-state lifespan measurement (QSSPC) according to the method of Sinton

The WCT-100, also known with the name Sinton instrument was developed by Ronald A. Sinton. It enables determination of the injection-dependent effective charge carrier lifespan τeff(Δn).

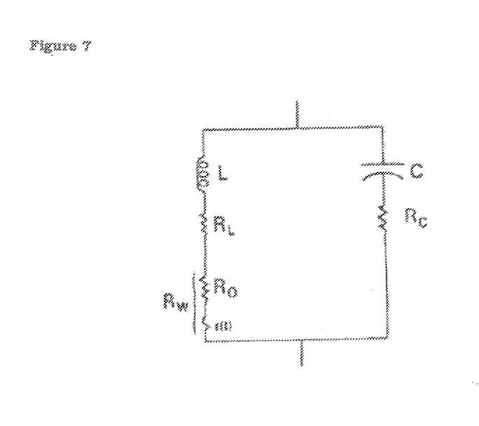

The instrument is based on the output absorption of semiconductors (in our case silicon wafers) which are subjected to the magnetic alternating field of a parallel oscillating circuit. As a result of the inductive coupling of the Si wafer to the oscillating magnetic field, eddy currents are produced therein. The limited conductivity of the Si wafer results in a part of the induced energy being radiated as heat. The conductivity of the wafer is directly proportional, in the range which is relevant for the evaluation, to the number of free charge carriers in the wafer. By short-term irradiation with the light of a flashlamp, additional free charge carriers are generated in the wafer and the conductivity of the wafer is increased. Therefore, the energy loss of the oscillating circuit is thus increased. This additional loss can be interpreted as new resistance r(t) in the oscillating circuit. A substitute circuit diagram of such an instrument is illustrated in FIG. 7: an oscillating circuit of an arrangement which is similar in principle to the Sinton instrument is shown, with L,C, the ohmic resistances of each branch R_{L}, R_{C}, and the resistance of the wafer R_{W}, subdivided into the non-illuminated part R₀ and the r(t) produced by light-induced charges: R_{W}=R₀+r(t), R₀ standing for the resistance of the wafer in the non-illuminated state.

With the quality of the oscillating circuit with non-illuminated wafer

$${Q}_{0}^{′} = \frac{{ω}_{r} L}{{R}_{L} + {R}_{C} + {R}_{0}}$$

there applies in the illuminated state:

$$Q ( t ) = \frac{{ω}_{r} L}{{R}_{L} + {R}_{C} + {R}_{0} + r ( t )} {=}^{R = {R}_{L} + {R}_{C} + {R}_{0}} \frac{{ω}_{r} L}{R} [ \frac{1}{1 + \frac{r ( t )}{R}} ] = {Q}_{0}^{′} [ 1 - \frac{r ( t )}{R} + {( \frac{t ( t )}{R} )}^{2} - … ]$$

By neglecting the terms of a higher order of the square brackets, there is produced:

Q(t)=Q₀′[1−k∈(t)]

with ∈ as the additional light-induced conductivity of the wafer and of the constant k which is much smaller than 1.

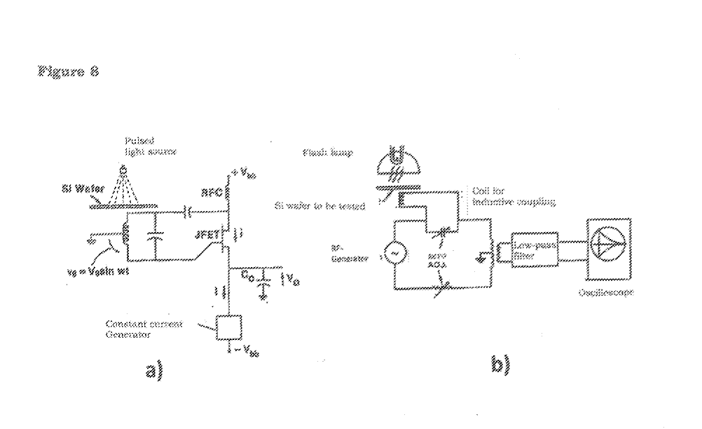

FIG. 8a shows a schematic circuit diagram of an arrangement which is similar in principle to the Sinton instrument (RFC=Radio Frequency Choke, JFET=Junction Field Effect Transistor). Since the WCT-100 is a commercial product, the precise circuit diagram is not known.

FIG. 8b shows a schematic circuit diagram of an arrangement which is similar in principle to the Sinton instrument. By changing the variable resistance and the variable capacity, adjustment of the conductivity of the wafer due to thermal excitation is implemented so that the charge carriers produced purely by the light excitation can be measured.

The voltage amplitude of the oscillating circuit (=amplitude of the gate voltage of the JFET, see illustration 8b) Vg is proportional to Q(t). The difference in voltage amplitude between illuminated and non-illuminated wafer is hence proportional to the photoinduced increase in the conductivity of the wafer.

In order to be able to measure the voltage V_{g} as far as possible without affecting the oscillating circuit, the transistor and the capacity C₀ form an infinite impedance detector with the (measurable) initial voltage V₀. The amplitude of V₀ was determined at

$${V}_{0} = \frac{Ψ QI}{2} \sqrt{\frac{L}{C}} cos ( \frac{∅}{2} ) - {V}_{T}$$

This applies to the interlinked magnetic flow Ψ, the angle of the conducting state of the transistor φ and of the transistor threshold voltage VT.

As a result of the preceding equations, a correlation between the light-induced conductivity of the wafer ∈ and the initial voltage amplitude V₀ is now produced.

The mathematical connection between ∈ and the injection density Δn is given by

∈=q·Δn·(μₙ+μₚ)·W

with the elementary charge q, the electron- or hole mobilities μn and μp and the wafer thickness W.

Hence a correlation between Δn and V₀ is shown and the temporal course of Δn is indirectly measurable.

Various evaluation methods exist for the effective lifespan. In the case of the quasi-static measurement, the illumination time is chosen to be very large relative to the carrier lifespan. This measuring method is best suitable for rather small lifespans. There thereby applies

$${τ}_{eff \cdot steady} ( Δ n ) = \frac{Δ n}{G}$$

The quasi-transient measurement is operated in precisely the reverse manner. The wafer there is subject to only a very short-term illumination in comparison with the charge carrier lifespan. The effective charge carrier lifespan results therefrom at:

$${τ}_{eff \cdot trans} ( Δ n ) = - \frac{Δ n}{d ( Δ n ) / d t}$$

Both measuring methods have the disadvantage that they provide good, i.e. low-error, results respectively only for a determined lifespan range. The generalised measurement was therefore proposed by H. Nagel et al., which measurement provides correct results irrespective of the illumination time and the lifespan. The lifespan is determined here via

$${τ}_{eff} ( Δ n ) = \frac{Δ n ( t )}{G ( t ) - \frac{d ( Δ n ( t ) )}{d t}}$$

This equation results from

$$\frac{1}{{τ}_{eff}} = \frac{1}{{τ}_{eff \cdot steady}} + \frac{1}{{τ}_{eff \cdot trans}}$$

The measurements in this work were implemented with the generalised method.

Because of the temporal intensity distribution of the light flash which produces a generation of additional free charge carriers, a plurality of lifespan points can be measured at differing injection densities with one measuring process. Thus determination of the dependence of the lifespan upon injection is possible within a wide injection range. In illustration B4, an example of a temporal course of the illumination intensity and of the photoconductivity which was recorded with the Sinton Instrument is illustrated.

In practice, the light-induced conductivity of the samples is correlated with the voltage observed at the output of the measuring apparatus by means of calibration samples.

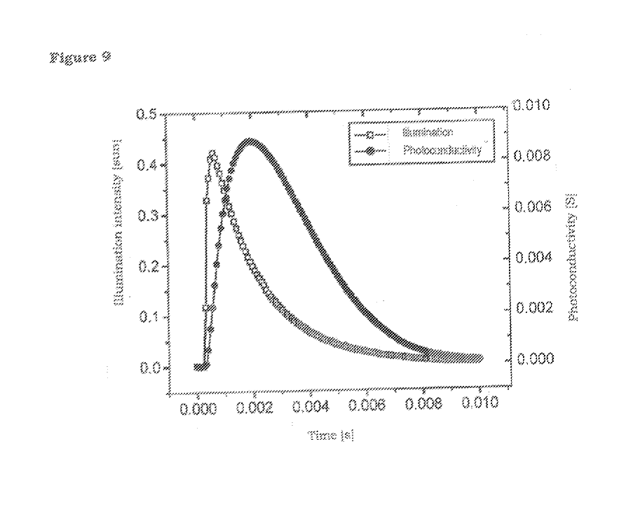

FIG. 9 shows an example of an illumination- and photoconductivity course; recorded with the Sinton instrument.

1. A solar cell with base, emitter and metallic contacts connected respectively electrically to the base and to the emitter and also at least one passivation layer for the front-side surface orientated towards the light source and/or the rear-side surface orientated away from the light source,
wherein the at least one passivation layer comprises hydrated aluminium nitride.

2. The solar cell according to claim 1,
wherein the at least one passivation layer has a refractive index, measured by means of ellipsometry at 600 nm, in the range of 1.9 to 2.2.

3. The solar cell according to claim 1,
wherein, on the passivation layer, at least one further layer, comprising a silicon oxide layer or a silicon nitride oxide layer, is deposited thereon.

4. The solar cell according to claim 1,
wherein, between the semiconductor component and the passivation layer, the semiconductor component has a native oxide layer or an oxide layer with a thickness of less than 3 nm.

5. The solar cell according to claim 1,
wherein the at least one passivation layer has a layer thickness of 1 to 200 nm.

6. A method for surface passivation of solar cells in which, on the front-side surface orientated towards the light source and/or on the rear-side surface of the semiconductor component orientated away from the light source, at least one passivation layer comprising hydrated aluminium nitride is deposited by means of vapour deposition from an atmosphere comprising aluminium, nitrogen and hydrogen.

7. The method according to claim 6,
wherein the vapour deposition is effected by means of physical vapour deposition (PVD), chemical vapour deposition (CVD), plasma-enhanced chemical vapour deposition (PE-CVD), chemical vapour deposition at atmospheric pressure (AP-CVD) or atomic layer deposition (ALD).

8. The method according to claim 6,
wherein, during the vapour deposition, nitrogen and hydrogen are used in atomic and/or molecular form.

9. The method according to claim 6,
wherein introduction of the hydrogen into the passivation layer is effected with at least one of the following techniques:
incorporation or implantation during the vapour deposition,
introduction by means of diffusion from the gas phase or from a layer comprising hydrogen which is deposited on the passivation layer.

10. The method according to claim 6,
wherein, during the vapour deposition, aluminium is used or generated in atomic or molecular form.

11. The method according to claim 6,
wherein, after the vapour deposition, the passivation layer is subjected to a temperature treatment at temperatures of 350 to 900° C.

12. The method according to claim 6, for the production of a solar cell with a base, emitter and metallic contacts connected respectively electrically to the base and to the emitter and also at least one passivation layer for the front-side surface orientated towards the light source and/or the rear-side surface orientated away from the light source, wherein the at least one passivation layer comprises hydrated aluminium nitride.

13. A method for producing a solar cell comprising a passivation layer, wherein the method comprises incorporating hydrated aluminium nitride in the passivation layer.
